(19) United States
(12) Patent Application Publication
(10) Pub. No.: US 2014/0027269 A1
(43) Pub. Date: Jan. 30, 2014

(54) SPUTTERING PROCESS FOR SPUTTERING A TARGET OF CARBON

(71) Applicants: Ulf Helmersson, Brokind (SE); Nils Brenning, Johanneshov (SE); Asim Aijaz, Linkoping (SE)

(72) Inventors: Ulf Helmersson, Brokind (SE); Nils Brenning, Johanneshov (SE); Asim Aijaz, Linkoping (SE)

(73) Assignee: Ionautics AB, Linkoping (SE)

(21) Appl. No.: 14/110,103

(22) PCT Filed: Mar. 26, 2012
(86) PCT No.: PCT/SE2012/050327

§ 371 Date: Oct. 4, 2013

(30) Foreign Application Priority Data
Apr. 7, 2011 (SE) 1150306-7

(51) Int. Cl. C23C 14/06

(52) U.S. Cl. CPC C23C 14/0605
USPC 204/192.15

(57) ABSTRACT

The sputtering process according to the present disclosure comprises providing a target consisting of carbon in a sputtering apparatus, introducing a process gas essentially consisting of a neon or a gas mixture comprising at least 60% neon into said apparatus, applying a pulsed power discharge to said target in order to create a plasma of said process gas, sputtering said target by means of said plasma. The process is able to ionize a significant amount of sputtered carbon atoms.

The present disclosure relates in general to a magnetron or hollow cathode sputtering process using a pulsed power supply. More specifically, it relates to a sputtering process for sputtering carbon.

### BACKGROUND

Magnetron sputtering is a sputtering technique widely used, for example, for coating substrates with functional coatings. A few examples of such functional coatings are wear resistant, decorative, or optical coatings. In accordance with the most common magnetron sputtering techniques, the power is supplied by direct current (DC) or radio frequency (RF).

It is relatively easy to achieve a large fraction of process gas ions in a magnetron sputtering process, whereas ions from the sputtered material are rare. Magnetron sputtering generally produces at the most 10% ionization of the sputtered target material. For many applications it is desired to increase the amount of ions of the sputtered material, since this means greater control of the deposition flux in terms of direction and energy.

Recently, a new magnetron sputtering technique called High Power Impulse Magnetron Sputtering (HiPIMS), or High Power Pulsed Magnetron Sputtering (HPPMS), has been developed. The process is disclosed for example in U.S. Pat. No. 6,296,742 and in Kouznetsov et al, “A novel pulsed magnetron sputter technique utilizing very high target power densities”, Surface and Coatings Technology 122 (1999) 290-293.

HiPIMS has the advantage that it is possible to significantly increase the ionization of the sputtered material compared to magnetron sputtering using DC or RF. This is achieved by the power to the magnetron being pulsed at very high powers. As a result of the pulsed power, the average power will not exceed the power which is possible to cool from the cathode (sputtering target). Therefore, the target is not overheated despite the high instantaneous power achieved during the process.

As a result of the high power of the pulse, a high density plasma will be achieved. The high density plasma increases the probability for sputtered atoms passing the plasma to be the subject for collisions with energetic plasma electrons that are able to ionize the atoms. In order for an electron to be able to ionize the atom, it is a prerequisite that the kinetic energy of the electron is greater than the ionization potential of the atom. In order to achieve a high probability for ionization, the kinetic energy of the electron must be significantly higher than the ionization potential of the atom.

The sputtering process is normally conducted with argon as process gas, i.e. as the sputtering gas. This means that the chamber will be filled with argon atoms and that a fraction of these will be ionized. The ionization potential for argon is about 15.76 eV, whereas most metals have a considerably lower ionization potential. For example, aluminum has an ionization potential of about 5.99 eV, titanium has an ionization potential of about 6.82 eV, and copper has an ionization potential of about 7.72 eV.

In the beginning of the development of HiPIMS, several attempts were made to ionize a large fraction of sputtered carbon. These attempts were however generally not successful [B. M. DeKoven, P. R. Ward, and R. E. Weiss, D. J. Christie, R. A. Scholl, W. D. Sproul, F. Tomasel, and A. Anders, Proceedings of the 46th Annual Technical Conference Proceedings of the Society of Vacuum Coaters, May 3-8, 2003, San Francisco, Calif., USA, p. 158 ]. FIG. 1 [J. A. Hopwood, in: J. A. Hopwood (Ed.), Thin Films: Ionized Physical Vapor Deposition, Academic Press, San Diego, 2000, p. 181] illustrates one example of a calculation of the probability of ionization for different materials. It is evident from the figure that carbon requires much higher plasma densities in order to be significantly ionized.

The reason for the difficulties of ionizing carbon is partly due to the fact that the carbon atom is relatively small geometrically, thus having a small surface which the electrons may collide with, and partly that the ionization potential is relatively high, about 11.26 eV. Thus, there is still a need to find a proper modification of the conventional HiPIMS process such that carbon or carbon containing materials may be sufficiently ionized when sputtered.

### SUMMARY

The object of the invention is to achieve a sputtering process for sputtering carbon, which process is able to ionize a significant amount of the sputtered carbon atoms.

The object is achieved by the process in accordance with claim 1. Embodiments are defined by the dependent claims.

The sputtering process according to the present invention comprises providing a target essentially consisting of carbon in a sputtering apparatus, introducing a process gas essentially consisting of neon or a gas mixture comprising at least 60% neon into said apparatus, applying a pulsed electric power discharge to said target in order to create a plasma of said process gas wherein the peak power of each pulse is at least 0.1 kW/cm² (wherein the area is the active surface area of the target), sputtering said target by means of said plasma and thus ionizing sputtered carbon atoms by means of said plasma.

Even though the sputtering process according to the invention primarily has been developed as a magnetron sputtering process, it may also be conducted as a hollow cathode sputtering process and thus conducted in a hollow cathode sputtering apparatus.

Significantly higher electron temperature, i.e. kinetic energy, of the electrons is achieved by the process according to the invention compared to for example a conventional HiPIMS process. This is mainly achieved by at least partly replacing argon used in conventional HiPIMS processes with neon, or a gas mixture comprising neon. Neon is a noble gas with higher ionization potential than argon, about 21.56 eV for neon compared to about 15.76 eV for argon. The temperature of the electrons that is needed to sustain a discharge in neon will therefore generally be higher than in a corresponding discharge in an easier ionized gas such as argon. With a significant amount of neon present in the discharge, it will be apparent to the skilled person how to select a pressure such that the electron temperature is significantly higher than in a pure argon discharge and the skilled person may easily achieve this by mere routine tests.

In accordance with an embodiment of the process, said gas mixture further comprises at least one second noble gas other than neon. The purpose of adding a second noble gas to the gas mixture is to facilitate ignition of the plasma. Therefore, the second noble gas is preferably argon or a noble gas which is heavier than argon, such as krypton.

The electron temperature of the plasma, which is possible to reach with a suitable selection of pressure, increases with an increasing fraction of neon in the gas mixture. Therefore, it is preferred that the gas mixture comprises at least 75% neon, more preferably at least 80% neon, most preferably at least 90% neon.

In accordance with one particularly preferred embodiment, the process gas consists essentially of up to 10% argon, the reminder being neon.

It is also feasible that the process gas comprises a reactive gas if desired. Moreover, it is possible to add a reactive gas to the process other than in the form of a process gas. For example, the reactive gas may be introduced outside of the plasma region of the apparatus and thus not participate in the sputtering process as such.

The process gas is suitably supplied to the sputtering apparatus in a continuous flow.

The magnetron sputtering process is a high power impulse magnetron sputtering process and the power is thus supplied in a pulsed mode to the target. In accordance with one preferred embodiment of the process, the peak power of each pulse is at least 1 kW/cm² wherein the area is the active surface area of the target.

Moreover, the duration of each pulse is preferably maximally 500 ps, more preferably maximally 100 ps, and the frequency of the pulses is preferably at least 50 Hz, more preferably at least 200 Hz.

In accordance with one embodiment of the process, the sputtered carbon atoms are collected on a substrate to which a bias of at least −25 V, preferably at least −50 V, is applied during the process. Such a bias results in an increase of the density of the collected carbon coating on the substrate. The process leads to a considerably higher amount of the sputtered carbon atoms being ionized during the process compared to a conventional HiPIMS process, which in turn leads to a greater control of the deposition flux in terms of direction and energy. Furthermore, this opens up for production of for example new types of tailor-made functional coatings comprising carbon.

### BRIEF DESCRIPTION OF THE DRAWINGS

FIG. 1 illustrates a calculation of the probability of ionization of different materials as a function of the electron density of the plasma assuming a constant electron temperature.

FIG. 2 shows the test results of the density of carbon films determined by X-ray reflectivity. The values are plotted as a function of the substrate bias for three cases: 1) only neon used as a process gas, 2) the process comprises a mixture of neon and argon with a partial pressure ratio of 2.5:0.5 (i.e. 83% neon), as well as 3) only argon is used as process gas.

FIG. 3 shows the test results of the carbon ions obtained for different gas mixtures determined using mass spectrometry.

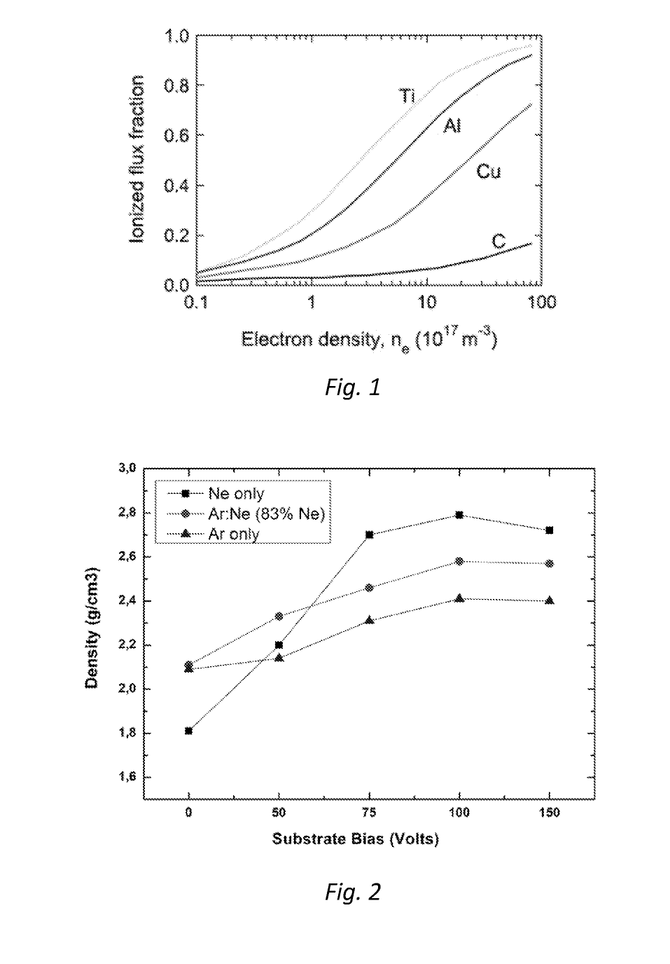

### DETAILED DESCRIPTION

The invention will be described below in more detail with reference to various embodiments. The invention is not limited to the specific embodiments described, but may be varied within the scope of the claims.

It should be apparent to the skilled person that the sputtered carbon atoms from the target may be in the form or single atoms, clusters, agglomerates or compounds without departing from the process according to the invention. Thus, where the term “carbon atom(s)” is used, it shall be interpreted to encompass not merely single atoms, but also clusters, agglomerates and compounds or the like.

Moreover, where percentages are given in the present disclosure in relation to the content of an element of a gas mixture, these percentages mean the percentage of the total pressure measured. It will be readily apparent to the skilled person that these percentages depend on the amount, the temperature as well as the volume.

The sputtering process according to the present invention is preferably a High Power Impulse Magnetron Sputtering (HiPIMS) process. For these high plasma density processes, the dominant mechanism for ionizing sputtered atoms is electron impact ionization. In order to understand how this mechanism works for different discharge conditions it is instructive to look at rate coefficients (k_{miz}) for such an event. These can be written in the Arrhenius form as shown in Equation 1, where k₀ and E₀ are constants that have to be extracted from experiments or computer simulations and Tₑ is the electron temperature of the plasma.

$${k}_{miz} ( {T}_{e} ) = {k}_{0} exp ( - \frac{{E}_{0}}{{T}_{e}} ) \qquad ( Eq . 1 )$$

In the case of atomic carbon, it has previously been reported that the rate coefficient is as disclosed in Equation 2, which constitutes an approximation.

k_{miz}(Tₑ)=0.4×10⁻¹³ exp(−12.6/Tₑ) (Eq. 2)

Using Equation 2, it is easy to understand that an increased electron temperature will increase the ionization of carbon. However, this expression does not disclose anything about the probability of having a collision between a carbon neutral and an electron in the process gas plasma, which is required in the first place.

Thus, in order to understand the ionization mechanism it is important to recognize that it is neutral material which is sputtered in a sputtering process, that the sputtered neutrals have a certain probability to undergo a collision with electrons in the process gas plasma, and that in such a collision, there is a probability that the neutral becomes ionized.

A much better expression for the overall trend of ionizing a sputtered neutral is therefore the ionization mean free path for the sputtered neutral, which is the average distance covered by the sputtered neutral before it is ionized. The mean free path depends on the rate coefficient for ionization, but also takes into account that the sputtered neutral will have a certain velocity, vₛ, traversing the plasma and that the plasma will have a certain density, which affects how often there will be a collision between the neutral and electrons of the plasma.

The ionization mean free path can thereby be expressed as disclosed in Equation 3. Britun et al. , Appl. Phys. Lett. 92 (2008) 141503, has reported that the velocity of a sputtered carbon neutral was found to be typically about 500 m/s.

$${λ}_{miz} = \frac{{v}_{s}}{{k}_{miz} {n}_{e}} \qquad ( Eq . 3 )$$

Other basic plasma parameters needed, such as the electron density, nₑ, and the electron temperature, Tₑ, depend heavily on the discharge conditions. This is why the ionization mean free path is given in the experimental findings below. Worth noting is that Tₑ is affecting the mean free path exponentially, which is not the case for nₑ. This means that small changes in electron temperature will have dramatic effects on the number of sputtered neutrals being ionized.

Thus, the sputtering process according to the present invention comprises providing a target essentially consisting of carbon in a magnetron sputtering apparatus or in a hollow cathode sputtering apparatus, introducing a process gas essentially consisting of a neon or a gas mixture comprising at least 60% neon into said apparatus, applying a pulsed power discharge to said target in order to generate a plasma of said process gas, sputtering said target by means of said plasma and thus ionizing sputtered carbon atoms by means of said plasma.

The target consisting of carbon may be produced in accordance with conventional techniques readily available to the skilled person. Moreover, the carbon may be in any form suitable for sputtering, for example in the form of graphite, or amorphous. It is obvious to the skilled person that the material of the target is in solid state when in the form of the target and electrically conductive in order to be suitable for sputtering.

As demonstrated by the experimental results from HiPIMS discharges reported below the fact that the process gas essentially consists of, or at least comprises a significant part of, neon makes it possible that a significant amount of the sputtered carbon atoms becomes ionized in the plasma. This is understood to be mainly due to the fact that the electron temperature, i.e. the kinetic energy, of the plasma is higher than if for example pure argon is used as process gas. Moreover, the experiments described below show that the mean free path of a carbon atom before ionization can be a factor of 30 shorter than in case pure argon is used as process gas, supposing the same operation pressure in the apparatus. Thus, the probability of ionization of a sputtered carbon atom is significantly higher compared to previously known magnetron sputtering processes. This in turn leads to a greater control of the deposition flux in terms of direction and energy and the possibility of for example production of new types of tailor-made functional coatings.

In any plasma based sputtering process, the energy of the electrons present in the plasma have an energy distribution, meaning that some electrons will always have lower energy than what is required to ionize the process gas, while other have higher energy. As the ionization potential of the process gas increases, the probability of ionizing sputtered neutrals increases provided that the process gas has a significantly higher ionization potential than that of the sputtered neutrals. This is because the electron temperature Tₑ will be determined mainly by the process gas ionization potential. By way of example, an electron having an energy of 20 eV is able to ionize argon and will thereafter share an energy of about 4.24 eV with the new free electron, which is not sufficient for any of them to ionize sputtered neutrals. However, an electron of 15 eV will not be able to ionize argon and will be much less affected by the argon process gas but will be able to maintain its energy in order to ionize sputtered target neutrals.

As previously mentioned, neon has an ionization potential of about 21.56 eV whereas argon has an ionization potential of about 15.76 eV. Even though the ionization potential of argon is higher than the ionization potential of carbon, the electron temperature of the plasma will not be high enough to allow any significant ionization of sputtered carbon neutrals. This is due to the fact that the electron temperature of the plasma is an average value of the electron energy distribution function, and thus that a certain number of electrons will have a higher electron energy whereas other electrons will have a lower electron energy. The number of electrons having a sufficient electron energy to ionize carbon atoms, when argon is used as process gas, is only enough to achieve a relatively low degree of ionization. However, in case of neon, a much higher degree of ionization of carbon atoms can be achieved due to the fact that a larger fraction of electrons of the plasma will have an energy above the threshold value for ionizing carbon, i.e. above 11.26 eV.

The sputtering process according to the invention is primarily developed as a magnetron sputtering process. However, it may also be conducted in a hollow cathode sputtering apparatus.

The sputtering process according to the present invention is able to ionize at least 20% of the sputtered carbon atoms, which may be compared to conventional magnetron sputtering processes which at the most are able to ionize about 10% of the sputtered carbon (in most cases less than about 5%). In fact, the magnetron sputtering process according to the invention enables ionization of at least 30% of the sputtered carbon atoms.

Depending on the sputtering apparatus used and the operating parameters, it may in some cases be difficult to ignite the plasma in case of the process gas essentially consisting of neon. This is due to the fact that the ionization potential is comparatively high for neon. Therefore, in accordance with one preferred embodiment of the invention, the process gas is a gas mixture comprising neon and at least one second noble gas which is easier to ignite, preferably argon. It is also feasible that the second noble gas is a noble gas which is heavier than argon, such as krypton. When igniting the plasma, the second noble gas of the gas mixture will initially ignite and assist in ionizing and igniting neon. Thereby, the formation of the plasma is drastically facilitated when such a second noble gas is added to the gas mixture. In order to achieve the desired effect, it is preferred that the second noble gas is present in an amount of at least 1%, preferably at least 2%.

In case the process gas is a gas mixture comprising a second gas, such as argon or another noble gas heavier than argon, the plasma may be more easily ignited than in a pure neon process gas. Noble gases which are heavier than argon are generally easier to ignite than argon. However, these may be more expensive than argon.

It is however essential that the process gas comprises a sufficient amount of neon in order to ensure that the sputtered carbon is sufficiently ionized. Therefore, the process gas should comprise at least 60% neon, preferably at least 75% neon, more preferably at least 90% neon.

In accordance with a particularly preferred embodiment, the process gas essentially consists of up to 10% argon and the reminder neon. Preferably, the process gas essentially consists of 2-10% argon and the reminder neon.

The sputtering process according to the present invention preferably utilizes a continuous flow of the process gas inside the chamber of the sputtering apparatus.

It is also possible that the process gas comprises a reactive gas adapted to react with the sputtered material in order to achieve a desired composition or microstructure of a coating on a substrate or workpiece. It is obvious to the skilled person that the reactive gas used is adapted to the purpose of such an addition. By way of example only, the reactive gas may for example be N₂ when desiring to make compounds like CNₓ or O₂ when desiring to make carbon-containing oxides.

Moreover, it is possible to add a reactive gas to the process other than in the form of a process gas. For example, the reactive gas may be supplied in a continuous flow separate from the flow of the process gas. Moreover, the reactive gas may be added to the sputtering apparatus in a region outside of the plasma, but prior to the collection of the sputtered material.

Furthermore, the reactive gas may or may not be a part of the plasma or be ionized by the plasma depending on the reactive gas used and the manner in which it is supplied to the process.

The magnetron sputtering process used in accordance with the present invention is preferably a high power impulse magnetron sputtering process and the power is thus supplied in a pulsed mode to the target. This has the benefit that the instantaneous power to the target may be very high but the average power supplied to the target over time may be low enough that the target can be effectively cooled such that overheating of the target is avoided. The peak power supplied in each pulse is typically at least 0.1 kW/cm², preferably at least 1 kW/cm², wherein the area relates to the active surface area of the target, i.e. the active cathode surface area.

The duration of the pulse should not be too long to ensure that the target is not unduly overheated. Generally, the duration of the pulse is maximally 500 ps, preferably maximally 200 ps, most preferably maximally 100 ps. Furthermore, the repetition frequency of the pulses preferably should be at least 50 Hz, preferably at least 200 Hz, most preferably at least 500 Hz.

Experimental Results—Sputtering Carbon with Varying Neon Content of the Process Gas

A HiPIMS system was used to sputter carbon from a graphite target. Argon and neon were used as process gas, i.e. sputtering gas, in varied quantities. The total gas pressure was however always the same, namely 15 mTorr.

The average power on the magnetron was about 30 W (the specific voltages and currents used are listed in Tables 1 and 2, respectively), and the magnetron had a diameter of about 2 inch, i.e. about 5.1 cm. The pulses had a duration of about 50 ps and a repetition frequency of about 600 Hz.

Langmuir probe measurements were performed using a cylindrical probe with the following dimensions of the probe tip: radius=65.5 μm, length=5 mm. The probe measurements were carried out at the axis of the magnetron (i.e. the probe tip was placed above the center of the circular magnetron). The below given results were recorded at about 80 μs after the initiation of the HiPIMS pulse, i.e. about 30 μs after pulse-off. This was done in order to reduce measurement uncertainties, which are common during the HiPIMS pulse due to the noisy plasma environment. It also means that the recorded values in the decay phase of the pulse are considerably lower compared to the conditions during the intense part of the HiPIMS pulse-on. The difference in the measured electron density is estimated to be around two orders of magnitude lower compared to the peak of the HiPIMS pulse and the measured electron temperature is likely to be reduced by about 1 eV based on estimations of results achieved by P. Sigurjonsson on a similar deposition system [P. Sigurjonsson, “Spatial and temporal variation of the plasma parameters in a high power impulse magnetron sputtering (HiPIMS) discharge,” Master's Thesis, Reykjavik: Faculty of Engineering, University of Iceland, 2008]. Still, the trends using the different gas mixtures will be the same and can readily be interpreted.

Measurements at about 2 cm away from the magnetron surface are given in Table 1 wherein nₑ is the electron density of the plasma, T_{e,cold} is the electron temperature of the cold part of a bi-Maxwellian electron energy distribution. From the data it is seen that when using the same average power in the HiPIMS discharge the electron temperature is increased from the pure argon case where T_{e,cold}=0.58 eV to a neon fraction of 83%, where T_{e,cold}=0.72, i.e. an increase of about 25%. This renders a much higher relative increase in the probability of ionizing collisions represented by the ionization mean free path, λ_{iz}, which decreases by a factor of 30. Another way of looking at the same thing is that the neutral carbon atom needs to travel (on average) 30 times as long in a pure argon discharge before undergoing an ionizing event, compared to a discharge containing 83% neon. As can be seen there is in all cases a reduction of λ_{iz} when neon is used compared to the case where only argon is used.

TABLE 1

| Neon | | | | | |
|---|---|---|---|---|---|
| fraction of | | | | | |
| the gas | Vₚₑₐₖ | Iₚₑₐₖ | T_{e, cold} | nₑ | λ_{iz} |
| mixture | [V] | [A] | [eV] | [m⁻³] | [m] |
| 0% | 656 | 2.8 | 0.58 | 9.65E+16 | 3.59E+08 |
| ~29% | 640 | 3 | 0.66 | 7.80E+16 | 0.27E+08 |
| ~50% | 632 | 3.2 | 0.61 | 6.78E+16 | 1.75E+08 |
| ~83% | 592 | 4 | 0.72 | 4.31E+16 | 0.11E+08 |

Measurements at about 4 cm from the magnetron surface are given in Table 2. The trend is weaker when moving out into the bulk plasma, but the same results as disclosed above in Table 1 are seen. However, the optimum values for the same Ne:Ar mixing conditions are not necessarily seen. From the data disclosed in Table 2 it is seen that using the same average power in the HiPIMS discharge the electron temperature is increased from the pure argon case where T_{e,cold}=0.66 eV to a neon concentration of 71%, where T_{e,cold}=0.77, i.e. an increase of about 17%. This renders an increase in the probability of ionizing collisions represented by the ionization mean free path, λ_{iz}, which decreases by a factor of about 10. Another way of looking at the same thing is that the neutral carbon atom in the Ne—Ar case needs to travel (on average) only 9% of the distance in the pure argon case before undergoing an ionizing event.

TABLE 2

| Neon | | | | | |
|---|---|---|---|---|---|
| fraction of | | | | | |
| the gas | Vₚₑₐₖ | Iₚₑₐₖ | T_{e, cold} | nₑ | λ_{iz} |
| mixture | [M] | [A] | [eV] | [m⁻³] | [m] |
| 0% | 656 | 3.0 | 0.66 | 6.77E+16 | 0.380E+08 |
| ~29% | 648 | 3.2 | 0.66 | 6.41E+16 | 0.360E+08 |
| ~50% | 640 | 3.2 | 0.66 | 5.77E+16 | 0.410E+08 |
| ~71% | 632 | 3.4 | 0.77 | 4.65E+16 | 0.035E+08 |

Further away from the magnetron, at about 6 cm, reliable measurements could be made already at about 60 μs from the initiation of the pulse, meaning that the electron temperature and electron density are generally found to be higher, since it is closer in time to the most intense part of the plasma (the peak of the HiPIMS pulse). Two electron distributions, cold and hot, were seen. The presence of two electron distributions for HiPIMS discharges has previously been reported, for example by Gudmundsson et al., Surf. Coat. Technology, 161, 249. 2002. Electron temperatures for both these distributions are given in Table 3, since the high-energy part of the electrons (represented by the hot electron distribution) is important in the ionization of carbon. The trends with increasing electron temperature remains the same as in the previous measurements: the electron temperature is increased from the pure argon case, where T_{e,cold} was 0.82 eV and T_{e,hot} was 2.69 eV, to a Ne:Ar concentration of 83% neon, where T_{e,cold} was 0.92 eV and T_{e,hot} was 3.97 eV. This corresponds to an increase of about 12% for the cold electron distribution and an increase of about 48% for the hot electron distribution.

As can be seen from the results given in Table 3, the ionization mean free path, λ_{iz}, decreases by about 84% and 80% for the cold and hot electron distributions respectively. This means that a neutral carbon atom needs to travel (on average) approximately 16-20% in the Ne-Ar case of the original distance in the pure argon case before undergoing an ionizing event.

TABLE 3

| Neon | | | | | | | |
|---|---|---|---|---|---|---|---|
| fraction | | | | | | | |
| of the | | | | | | | |
| gas | Vₚₑₐₖ | Iₚₑₐₖ | T_{e, cold} | T_{e, hot} | nₑ | λ_{iz, cold} | λ_{iz, hot} |
| mixture | [M] | [A] | [eV] | [eV] | [m⁻³] | [m] | [m] |
| 0% | 664 | 3.20 | 0.82 | 2.69 | 8.18E+16 | 7.62E+5 | 16.50 |
| ~29% | 648 | 3.20 | 0.84 | 3.11 | 1.02E+17 | 3.71E+5 | 7.05 |
| ~50% | 640 | 3.20 | 0.91 | 2.69 | 1.10E+17 | 1.25E+5 | 12.30 |
| ~71% | 616 | 3.40 | 0.86 | 3.10 | 1.04E+17 | 2.61E+5 | 7.07 |
| ~83% | 600 | 3.80 | 0.92 | 3.97 | 8.92E+16 | 1.20E+5 | 3.35 |

### Experimental Results—Carbon Film Density Determination by X-ray Reflectivity (XRR)

For solid materials, x-rays have a critical angle for total external reflection. The critical angle determination allows for obtaining the mass density of the solid. X-ray reflectivity (XRR) can therefore used for the determination of the critical angle and hence the density of thin films. In XRR, the reflectivity of films is recorded by varying the x-ray incident angle (as measured between the x-ray beam and the surface of the solid) from a low value such as 0.1° to a high value such as 3° . The reflected intensity increases with an increase in the incidence angle until a critical angle ‘θ_{c}’ is reached. After the critical angle the reflected intensity decreases rapidly. Once the critical angle is determined, Equation 4 can be used to obtain the density of films.

$${ρ}_{m} = \frac{{πθ}_{C}^{2} A}{Z {λ}^{2} {r}_{o} {N}_{A}} \qquad ( Eq . 4 )$$

where ρₘ is the mass density of films, θ_{c} is the critical angle, A is the mass number of the material, Z is the charge number of the material, λ is the wavelength of x-ray radiation, rₒ is the classical electron radius, and N_{A} is the Avagadro's number.

The carbon films were grown at various negative substrate biases with typical argon only condition and with a mixture of neon and argon using a partial pressure ratio of 83% neon. The average power was 42 W, and a frequency of 600 Hz and a duration of the pulses of 25 μs were used. The pressure was 15 mTorr during these tests. The results for the critical angle and density of films are presented in Table 4 and the results of density of the films are shown in FIG. 2.

Furthermore, carbon films were also grown at various negative substrate biases using only neon. The same conditions as given above were used except for the pressure which was 35 mTorr. The result is also shown in FIG. 2.

TABLE 4

| Substrate | θ_{c} | ρₘ | θ_{c} | ρₘ |
|---|---|---|---|---|
| Bias | [degree] | [g/cm⁻³] | [degree] | [g/cm⁻³] |
| [V] | 83% Ne | 83% Ne | Ar only | Ar only |
| 0 | 0.2105 | 2.11 | 0.2095 | 2.09 |
| −50 | 0.2213 | 2.33 | 0.2122 | 2.14 |
| −75 | 0.2272 | 2.46 | 0.2201 | 2.31 |
| −100 | 0.2328 | 2.58 | 0.2248 | 2.41 |
| −150 | 0.2322 | 2.57 | 0.2247 | 2.4 |

As can be seen from the results presented in Table 4, there is a clear density increase in all carbon films sputtered using the 83% neon mix as compared to using only argon. Interesting in the present case are the reference values of the densities of diamond, graphite, and tetrahedral amorphous carbon (ta—C), which are summarized in Table 5.

In all cases using the Ne-Ar mix and substrate bias the density values are greater than that of sputtered C meaning that these coatings are more diamond-like (with a greater number of sp3-bonds).

TABLE 5

| | ρₘ |
|---|---|
| | [g/cm⁻³] |
| Graphite | 2.267 |
| Diamond | 3.515 |
| Sputtered C | 2.2 |
| ta-C | 3.1 |

### Experimental Results—Mass Spectrometry Measurements of Carbon Ions

Mass spectrometry measurements of carbon ions were performed on carbon ions obtained during a plasma sputtering process using an average power of 42 W, a frequency of 600 Hz, duration of pulse 25 μs and pressure 15 mTorr.

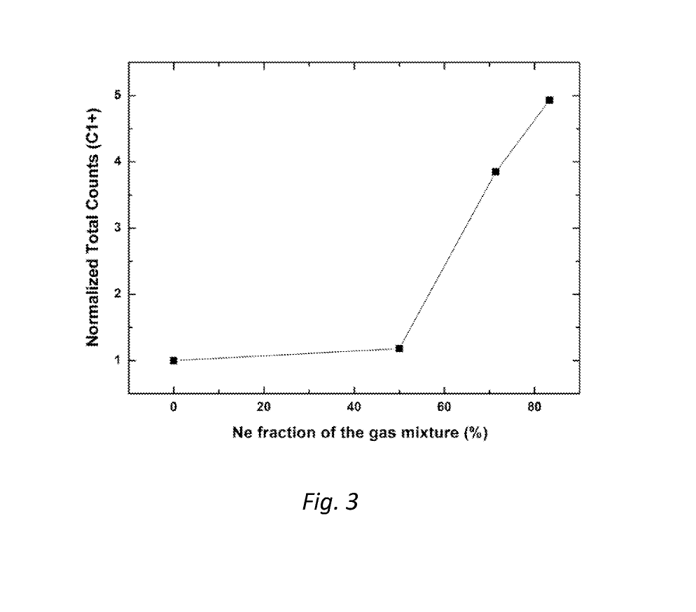

The result is shown in FIG. 3 in the form of the total carbon ions (C1+) obtained for different gas mixtures, i.e. different contents of neon, starting with pure argon. The counts are normalized to the pure argon case. A clear increase of carbon ions with increasing fraction of neon is shown.

1. Sputtering process for sputtering a target consisting of carbon, the process comprising
providing a target essentially consisting of carbon in a magnetron sputtering apparatus or in a hollow cathode sputtering apparatus,
introducing a process gas into said apparatus, the process gas essentially consisting of neon or a gas mixture comprising at least 60% neon,
applying a pulsed electric power discharge to said target in order to create a plasma, wherein the peak power of each pulse is at least 0.1 kW per each cm² of the active target surface area,
sputtering said target by means of said plasma and ionizing sputtered carbon atoms by said plasma.

2. Sputtering process in accordance with claim 1 whereby said gas mixture further comprises at least one second noble gas other than neon.

3. Sputtering process in accordance with claim 1 wherein said gas mixture comprises at least 75% neon.

4. Sputtering process in accordance with claim 2 wherein said at least one second noble gas is argon.

5. Sputtering process in accordance with claim 4 wherein said process gas essentially consists of up to 10% of argon, the remainder being neon.

6. Sputtering process in accordance claim 2 wherein said at least one second noble gas is krypton.

7. Sputtering process in accordance with claim 1 wherein said gas mixture further comprises a reactive gas.

8. Sputtering process in accordance with claim 1 wherein the peak power of each pulse is at least 1 kW per each cm² of the active target surface area.

9. Sputtering process in accordance with claim 1 wherein the duration of each pulse is maximally 500 μs.

10. Sputtering process in accordance with claim 1 wherein the frequency of the pulses is at least 50 Hz.

11. Sputtering process in accordance with claim 1 comprising collecting sputtered carbon atoms on a substrate and wherein a bias of at least −25 V, is applied to said substrate.

12. Sputtering process in accordance with claim 11 comprising collecting sputtered carbon atoms on a substrate and wherein a bias of at least −50 V is applied to said substrate.
